(19) United States
(12) Patent Application Publication
(10) Pub. No.: US 2004/0159793 A1
(43) Pub. Date: Aug. 19, 2004

(54) Carbon-based photodiode detector for nuclear medicine

(76) Inventors: Christoph Brabec, Erlangen (DE); Samir Chowdhury, Chicago, IL (US); John C. Engdahl, Lake Forest, IL (US); Jinhun Joung, Algunquin, IL (US); Douglas Jay Wagenaar, South Barrington, IL (US); Thomas von der Haar, Nurnberg (DE)

Correspondence Address: Siemens Corporation, Intellectual Property Department, 170 Wood Avenue South, Iselin, NJ, 08830, US

(21) Appl. No.: 10/369,944

(22) Filed: Feb. 19, 2003

(51) Int. Cl. G01T 1/24

(52) U.S. Cl. 250/370.11

(57) ABSTRACT

A radiation detection that employs an array of carbon-based photodetectors (CBPD) to convert scintillation photons into electronic signals is disclosed. According to one embodiment, the carbon-based photodiode consists of a p-type semiconductor and an n-type semiconductor. Further, the p-type semiconductor and n-type semiconductors are a conjugated polymer and a media comprised of fullerenes respectively.

### BACKGROUND

The invention relates to radiation detectors in general, and to radiation detectors which include semiconductor photodiodes for nuclear medicine in particular.

Nuclear medicine imaging assesses the radionuclide distribution within a patient after the in vivo administration of radiopharmaceuticals. Imaging systems that assess radionuclide distribution include radiation detectors and acquisition electronics. The imaging systems detect x-ray or gamma ray photons derived from the administered radionuclides. Single photon emission imaging and coincidence imaging are two forms of nuclear medicine imaging that are currently in common use. In single photon emission imaging, the radionuclide itself directly emits the radiation to be assessed. For example, in Single Photon Emission Computed Tomography (SPECT), γ-emitting radionuclides such as ^{99m}Tc, ¹²³I, ⁶⁷Ga and ¹¹¹In may be part of the administered radiopharmaceutical. The imaging system often uses a lead collimator to eliminate all photons but those photons traveling in a desired direction. For example, a parallel hole collimator eliminates photons traveling in all directions except those almost perpendicular to the surface of the detector. The energy of emitted photons as well as their location of origin may then be accumulated until a satisfactory image is obtained.

Coincidence imaging eliminates the need for such a collimator by relying on the detection of two photons at different detectors at nearly the same time. An example of coincidence imaging in current clinical use is Positron Emission Tomography (PET). In PET, β⁺-emitting radionuclides such as ¹¹C, ¹³N, ¹⁵O, ¹⁸F, ⁶⁸Ga, ⁸²Rb are part of the administered radiopharmaceutical. The emitted positrons react with electrons within the patient's body, the annihilation creating two 511 keV photons emitted in opposite directions. The two photons are then detected within a certain time window, generally in the nanosecond range, of each other.

Another example of coincidence imaging, not currently in clinical use, is the detection of two photons resulting from a first and second Compton scattering event within a first and second detector element. Again, a nanosecond range time window is used to determine “coincident” photons.

Radiation detectors used in nuclear medicine imaging need to absorb x- or gamma-ray photons in an energy range typically between 1 keV and several MeV. These imaging photons are the photons either directly emitted or resulting from radionuclides within a patient. Radiation detectors in nuclear medicine imaging systems may be classified into the two categories of detectors: direct electronic detectors and scintillation detectors. Direct electronic detectors convert the imaging photons directly into an electronic signal which may then be measured. Typically, a direct electronic detector has an electric field imposed within the bulk of the detector material. The purpose of the electric field is to separate positive and negative charge carriers generated by the imaging photons. The charge carriers establish a detectable electric signal. One type of direct electronic detector includes gas-filled ionization chambers, proportional counters and Geiger counters. A second type of direct electronic detector includes single element intrinsic semiconductor detectors comprised of Germanium, Silicon or other semiconductor elements, as well as single element doped semiconductor detectors. A third type of direct electronic detector includes compound semiconductors such as Cadmium Telluride, Cadmium Zinc Telluride, Mercuric Iodide, Thallium Bromide or other compounds. In the field of radiation detection, the term “semiconductor radiation detector” refers to the intrinsic, doped, or compound semiconductors in which the x- or gamma-ray photons initially interact and create electron-hole pairs in the semiconductor material.

Semiconductor detectors, whether they are intrinsic, doped, or compound, have unique properties which make them more challenging to incorporate into clinical medical imaging. Intrinsic and doped semiconductors generally are inefficient in photon detection due to their relatively low atomic number compared with other materials used to detect x- or gamma-ray photons, such as NaI or CsI crystals. They also must be cooled to liquid nitrogen temperatures for clinical applications in order to sufficiently decrease thermally dependent electrical noise. Compound semiconductors provide acceptable efficiency and operation at room temperature due to their high atomic number and large band gap energy. However, they are relatively expensive and difficult to produce compared with NaI or CsI crystal based detectors. Furthermore, semiconductor detectors have some common technical problems which hinder commercial application. Among these problems is the selection of contact metals to connect to the semiconductor detector. Another problem is the surface passivation of the semiconductor material. Another problem is the mechanical fragility of the material. Another problem is the resistivity of the material which contributes to the leakage current and therefore the noise introduced into the overall detection system. Yet another problem is the lack of uniformity stoichiometry and its effect on performance.

Scintillation detectors convert single x- or gamma-ray photon interacting within a scintillator material into a number of photons of lower energy. Generally these scintillation photons have a frequency in the range of visible light. The number of these scintillation photons is proportional to the energy of the initial single x- or gamma-ray photon. In scintillation detectors, the scintillation photons must then be converted to a measurable electrical signal.

The Anger camera pioneered this approach in the 1950s is and more fully described in U.S. Pat. No. 3,011,057. The Anger camera consists of a NaI crystal as a scintillation material, and an array of photomultiplier tubes (PMTs). In operation, x-ray or gamma ray photons cause scintillation events in the NaI crystal. The resulting scintillation photons then impinge the different PMTs. The different signals amplified by the different PMTs yield information about the location of the scintillation event within the NaI crystal.

In the current art, a variety of crystals which act as scintillator materials may be used, depending on the application (e.g., SPECT or PET), and the cost, reliability, resolution and speed of imaging required. Scintillator crystals include sodium iodide (NaI), cesium iodide (CsI), bismuth germanate (BGO), barium fluoride (BaF₂), lutetium oxyorthosilicate (LSO), and others.

Regardless of the particular scintillator material used, the scintillation photons produced must be converted into an electrical signal to be analyzed. PMTs are still often used to convert scintillation photons into a measurable electrical signal. A PMT includes a photocathode and a series of dynodes which act as electron multipliers, both of which are sealed in an evacuated glass tube. There is an anode at the opposite end of the tube. An input window is optically coupled to the scintillation crystal to allow scintillation photons to strike the photocathode. Scintillation photons incident on the photocathode cause the photocathode to emit an electron due to the photoelectric effect. Each electron emitted from the photocathode is accelerated and focused onto another electrode called a dynode which subsequently emits additional electrons (e.g. 5-6 new electrons emitted per each incident electron). Each of the series of dynodes repeat this reaction until a final large cluster of electrons is collected at the anode, creating a pulse that is processed by the acquisition electronics.

PMTs are extremely sensitive to low levels of light. However, PMTs have a number of drawbacks. They require a high voltage (>800 V) for effective operation, PMTs are vulnerable to drifting in performance, especially early in their life cycle. PMTS are susceptible to mechanical failure affecting reliability. PMTs are susceptible to magnetic fields, such as from the MRI devices (and even from the earth's comparatively weak magnetic field). PMTs are also physically bulky, which is problematic as the size of the PMTs determines and limits the intrinsic spatial resolution of a detector system. The size of the PMTs also increases the amount of lead shielding required to prevent x- or gamma-ray photons from entering the detector, except through the collimator. The shielding weight and physical size of the camera increases costs, especially in tomographic imaging where the detectors must be mechanically moved.

In addressing the above problems, photodetectors composed of an array of solid-state photodiodes have been used in place of PMTs. See, for example, U.S. Pat. No. 5,171,998. Inorganic photodiodes, generally comprising various forms or compounds of silicon, address some of the problems of PMTs. Inorganic photodiodes are more stable over their life cycle and are mechanically more robust. Inorganic photodiodes are not susceptible to magnetic fields, and are much smaller and lighter. However, inorganic photodiodes have their own disadvantages. They are susceptible to radiation damage. In general, they have a poor spectral response to scintillation photons from scintillation crystals such as NaI. In silicon based photodiodes in particular, their low band gap yields thermally generated leakage current, which acts to increase noise in the electronics. Silicon photodiodes may require cooling to lower such leakage current to acceptable levels.

Therefore, there remains a need in the radiation detection art for a photodiode which keeps the improvements of inorganic photodiodes over PMTs, but addresses the problems of inorganic photodiodes.

One aspect of the present invention is a radiation detector having a scintillator and an array of carbon-based photodiodes. A further aspect of the present invention is a radiation detection system having a scintillator, an array of carbon-based photodiodes, and associated electronics. A further aspect of the present invention is a radiation detector having a scintillator and a composite of conjugated polymers and fullerenes (or nanoparticles) optically coupled to the scintillator, wherein the composite acts as a photodiode.

A further aspect of the present invention is a method of detecting gamma rays. A gamma ray photon is received in a scintillator, which then emits a lower wavelength photon. A carbon-based photodiode optically coupled to the scintillator receives the lower wavelength photon, creating an electron hole pair in the carbon based photodiode. An electrical characteristic of the carbon-based photodiode changes in reaction to receiving the lower wavelength photon.

A further aspect of the present invention is a radiation detection assembly having a gantry, a computer, and a radiation detector system. The radiation detector system is mounted to the gantry. The computer is in communication with the radiation detector system. The radiation detector system includes a scintillator crystal, a carbon-based photodiode, and associated electronics.

### BRIEF DESCRIPTION OF THE DRAWINGS

The above description, as well as further objects, features and advantages of the present invention will be more fully understood with reference to the following detailed description of the preferred embodiments, when taken in conjunction with the accompanying drawings, wherein:

FIG. 1 is a planar view of a radiation detection system for use with the apparatus and methods in accordance with one embodiment of the invention.

FIG. 2 is a side view of a photodiode in accordance with an embodiment of the present invention.

FIG. 3 is a side and exploded view of the photodiode of FIG. 2.

FIG. 4 is a diagram of energy levels of the photodiode of FIG. 3 in a flat band state.

FIG. 5 is a diagram of energy levels of the photodiode of FIG. 3 in a short circuit state.

FIG. 6 is a side view of a photodiode in accordance with another embodiment of the present invention.

FIG. 7 is a side and exploded view of the photodiode of FIG. 6.

FIG. 8 is a diagram of energy levels of the photodiode of FIG. 6 in a flat band state.

FIG. 9 is a diagram of energy levels of the photodiode of FIG. 6 in a short circuit state.

FIG. 10 is a graph of one aspect of the electrical characteristics of the illustrative embodiment of the present invention.

FIG. 11 is a graph of another aspect of the electrical characteristics of the illustrative embodiment of the present invention.

FIG. 12 is a graph of another aspect of the electrical characteristics of the illustrative embodiment of the present invention.

FIG. 13 is a side view of a radiation detection assembly for use with the apparatus and methods in accordance with one embodiment of the invention.

### DETAILED DESCRIPTION

Carbon-based materials are traditionally considered to act as insulators. However, many classes of carbon-based material have been found which instead act as conductors, or as semiconductors. Such carbon-based semiconductors may have optoelectronic properties similar to inorganic semiconductors (though the physical mechanisms responsible may be different). Specifically, some carbon-based semiconductors can act as photoemitters or photodetectors, and have been used as such in applications such as image display flat panels, multi-spectral image sensing, and photovoltaic (solar) cells.

Photodiodes, two terminal devices allowing conduction in only one direction which generate a current in response to light, may be constructed from carbon-based semiconductors to perform as photodetectors. Such carbon-based photodiodes (CBPDs) may be responsive to the wavelengths of scintillation photons and therefore may be used in place of both inorganic semiconductor photodiodes and PMTs in scintillation detectors.

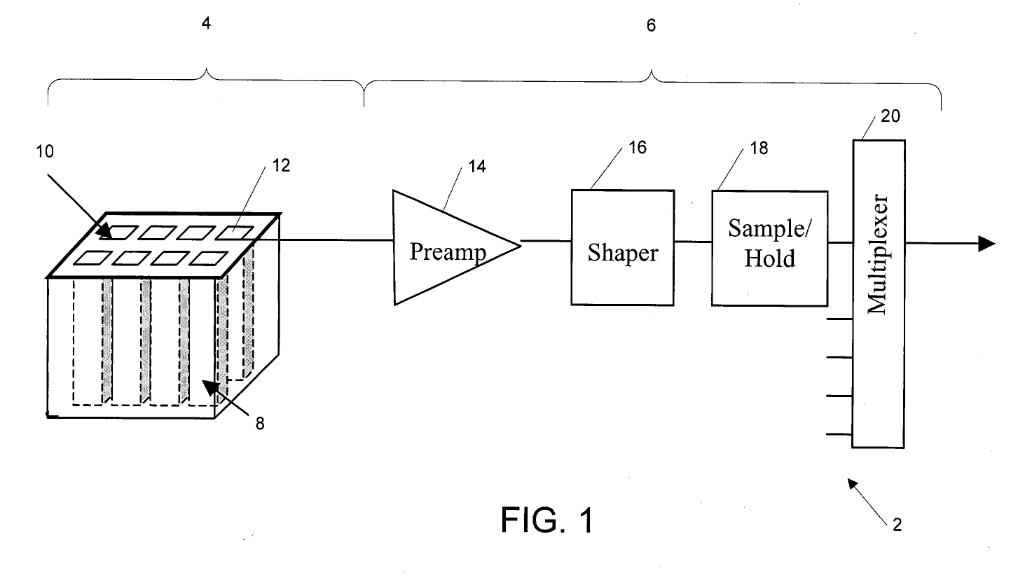

FIG. 1 illustrates an embodiment of the present invention. Radiation detector system 2 includes the radiation detector 4 and data acquisition circuits 6. The radiation detector 4 includes a scintillator 8 and an array of CBPDs 10. The array of CBPDs 10 acts as a photodetector. However, a single CBPD may form such a photodetector. Furthermore, the CBPDs need not be identical to one another, although identical photodiodes in an array will increase ease of manufacture. CBPD 12 is a single photodiode of the array 10. The acquisition circuits 6 include a low noise preamp 14 and a shaper circuit 16. The shaper circuit 16 acts as an integrator. A sample/hold circuit 18 delivers the signal to the multiplexer 20 at the appropriate time. Although only a single low noise preamp 14, shaper circuit 16, and sample/hold circuit 18 are shown for CBPD 12, each CBPD will require such a set of circuits. Multiplexer 20 then sorts the various signals from the one or more CBPDs of the CBDP array 10.

Scintillator 8 may be any one of a number of materials, including but not limited to, NaI, NaI(TI), CsI, CsI(TI), CsI(Na), CdWO, BGO, LSO, HgI, YAG(Ce), YSO(Ce), YAP(Ce), LUAG, GSO, PWO, BaF, CsF, CsF(Eu), and ZnS(Ag). Scintillator 8 may be monolithic or pixilated (as shown in FIG. 1) with reflectors to maximize light collection.

The above embodiment of the present invention contemplates the use of any type of CBPD. However, different types of CPBDs yield superior performance. Carbon-based photodiodes may be distinguished according to their chemical structure and associated method of production.

In a particular embodiment of the present invention, CBPD 12 of CBPD array 10 is constructed from small organic molecules. Illustrative examples of such small organic molecules include phtholcynines and merocynines, as well as certain forms of fullerenes. CBPDs constructed from such small organic molecules are typically formed by a vapor deposition process. CBPDs constructed from such small organic molecules may form PIN diodes, Schottky diodes, and other types of photodiodes known in the electronics art.

In another particular embodiment of the present invention, CBPD 12 of CBPD array 10 is constructed from pristine polymers. Pristine polymers have no other materials deliberately introduced to them, but rather are purified. Pristine polymers are typically produced by a solution process that is similar to other solution processes known in the plastic arts. CBPDs constructed form such pristine polymers may form PIN diodes, Schottky diodes, and other diodes known in the electronics art. CBPDs formed from pristine polymers must be operated in a photovoltaic mode (no voltage bias applied).

A specific kind of pristine polymer which may be used to form a CBPD is a π-conjugated polymer. A π-conjugated polymer has alternating single and double or single and triple bonds along its polymer chain. The energy of the electrons in both double and triple bonds is much higher than the energy of the electrons in single bonds. The alternating bonds of different energies create an energy band gap which is much smaller that that of a typical polymer. Thus, π-conjugated polymers may act as semiconductors for constructing a CBPD.

Generally, such π-conjugated polymers are donor or p-type semiconductors. Therefore, pairing π-conjugated polymers with acceptor, or n-type semiconductors enhances performance. This class of polymer/small molecule CBPDs may also be produced by a solution process.

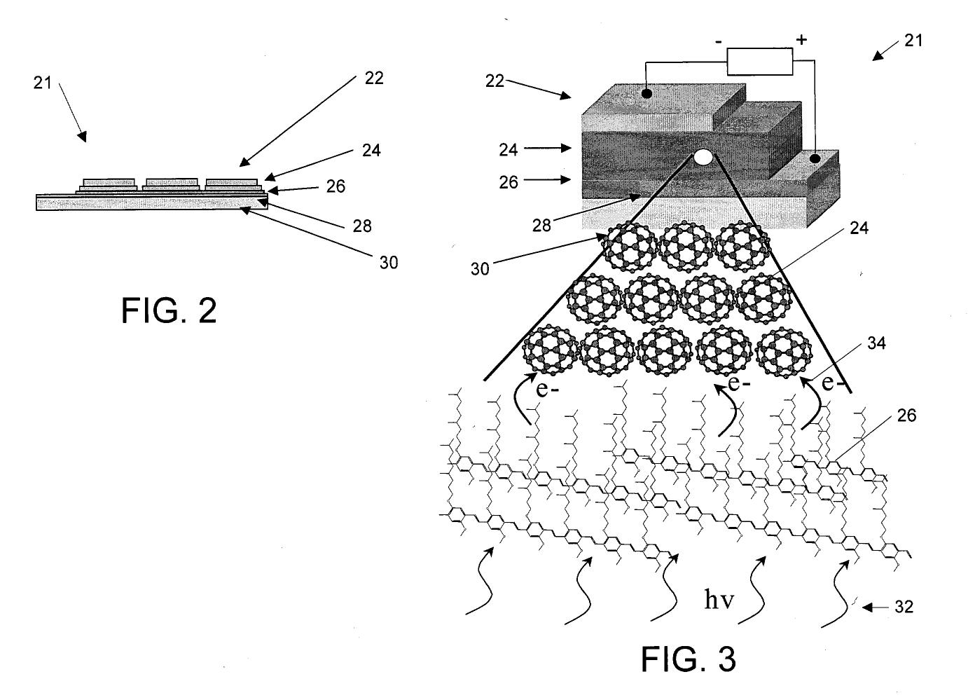

FIG. 2 and FIG. 3 show a CBPD 21 of another embodiment of the present invention which illustrates such a polymer/small molecule CBPD. FIG. 2 shows the physical structure of the CBPD. In this embodiment, an electrode 22 is composed of gold, an n-type semiconductor 24 is composed of C60 (buckminsterfullerene), a p-type semiconductor 26 is composed of the conjugated polymer poly [2-methoxy, 5-(3′,7′-dimethyl-octyloxy)]-p-phenylene vinylene (MDMO-PPV), a transparent electrode 28 is composed of indium tin oxide (ITO), and a substrate 30 is glass. FIG. 3 shows a close view of the CBPD 21 as well as a detail of the planar bilayer heterojunction of C60 24 and the MDMO-PPV 26.

In operation, scintillator photons 32 pass through the glass substrate 30 and the transparent ITO electrode 28. The scintillator photons 32 are absorbed by either MDMO-PPV 26 of C60 24, depending on the wavelength of the scintillator photons 32. The absorption of scintillator photons 32 creates corresponding excitons. The exition then diffuses towards the planar bilayer heterojunction. The excitions then split into their component charge carriers at this heterojunction under the natural electric field present. Electrons 34, the negative charge carriers are accepted by the n-type semiconductor C60 24 and diffuse towards one electrode. The positive charge carrier (a hole) will be accepted by the MDMO-PPV 26 and diffuse towards the opposite electrode. Thus a photocurrent may flow when photons are absorbed by the CBPD 21

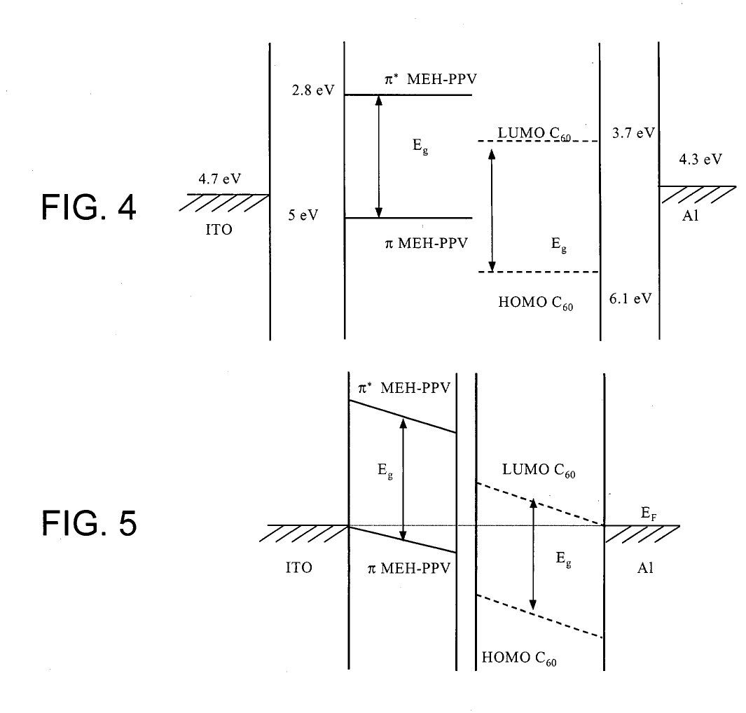

FIG. 4 shows the some possible energy levels for flat band conditions in the CBPD 21 for illustrative purposes. The energy levels are the escape energies for an electron in the material, in electron volts. A flat band condition will occur when a forward bias (or no bias) is applied to the CBPD 21. A forward bias condition occurs when a positive voltage is applied to the p-side of a photodiode with respect to the n-side. The natural potential difference between the electrodes is reduced. LUMO stands for Lowest Unoccupied Molecular Orbital and HOMO for Highest Occupied Molecular Orbital FIG. 4 clearly shows the spatial discontinuity in the energy of electron states across the planar bilayer heterojunction. FIG. 5 illustrates the energy levels for short circuit conditions in the MDMO-PPV/C60 system 23. Under this condition, the potential difference between electrodes is zero. The energy of electron states decreases across the CBPD 21. In practical terms, this increases the distance from the planar bilayer heterojunction where a created electron-hole pair will be converted into a photocurrent. Application of a reverse bias will increase this effect.

Scintillation photons in the visible light spectrum may penetrate a carbon-based material up to approximately 150 nm. If the layer of MDMO-PPV 26 of CBPD 21 shown in FIG. 3 is of approximately 150 nm in thickness it will thus absorb practically all scintillator photons incident upon it. However, only a fraction of those photons will be converted into measurable current. Though a photon may be converted into an electron-hole pair throughout the MDMO-PPV 26, recombination of the charge carriers and other effects will prevent the photons energy from being added to the photocurrent. Only charge carriers created near the planar bilayer heterojunction interface will be converted into measurable current as the electrons of the electron-hole pairs will have the opportunity to the transported to the acceptor semiconductor C60 24 before recombination.

A CBPD composed of a composite (or blend) of p-type semiconductors and n-type semiconductors can avoid this spatial limitation of the planar heterojunction. Such a composite contains nanoscopic p-n junctions all throughout its volume, creating a “bulk heterojunction.” The bulk heterojunction of such a composite is an interpenetrating, phase separated, donor-acceptor network composite. In this geometry, a photon absorbed anywhere in the volume of the composite 44 yields a free hole and an electron, the positive and negative charge carriers. Such bulk heterojunction geometries have shown to have much better performance as photodiodes. External quantum efficiency of 80% for a photodetector in photovoltaic mode has been shown in such composites.

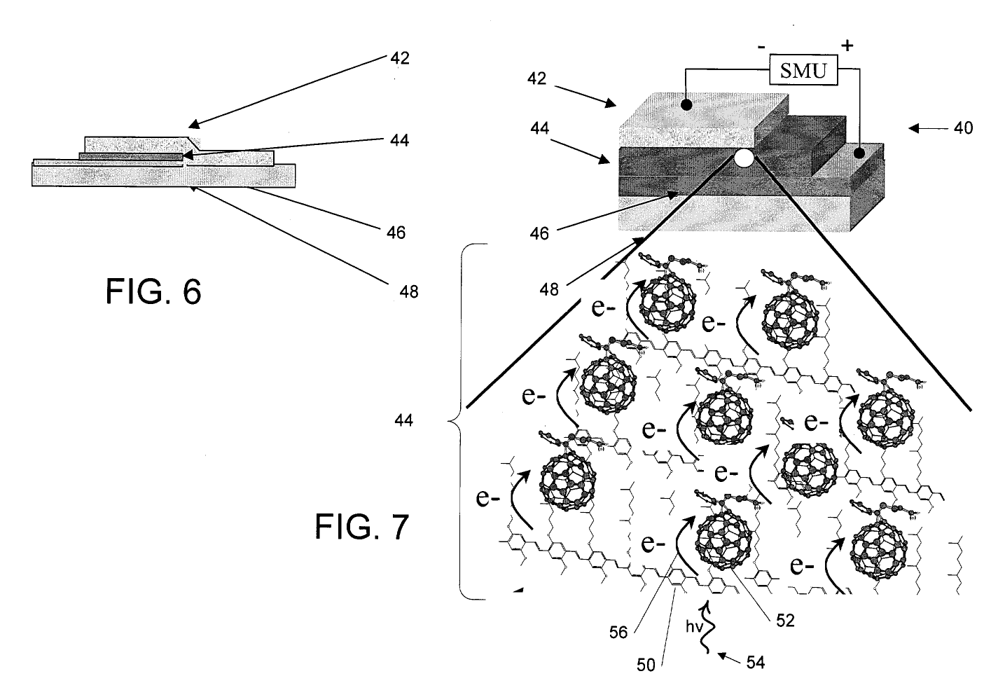

FIG. 6 and FIG. 7 show a CBPD 40 for a preferred embodiment of the present invention. CBPD 40 includes a composite having bulk heterojunction geometry. FIG. 6 shows an electrode 42, a composite 44, a transparent electrode 46, and a substrate 48. As a specific example, the electrode 42 may be one of a number of materials including, but not limited to, Ca, Ba, Mg, Al, and LiF—Al. The transparent electrode 46 may be one of a number of materials including, but not limited to ITO and poly(3,4-ethylenedioxythiophene)(polyaniline) (PEDOT(PANi)). The substrate may be glass or other relatively inert but transparent or translucent material.

FIG. 7 further shows close up and exploded views of composite 44. Composite 44 is composed of a blend of MDMO-PPV 50 and methanofullerene [6,6]-Phenyl C61-butyric acid methyl ester (PCBM) 52. PCBM 52 is a soluble fullerene, and thus lends itself to the formation of composites. In operation, CBPD 40 is different from CBPD 21. Scintillator photons 54 directly generate electron-hole pairs within the bulk of the MDMO-PPV/PCBM composite 44, wherever a PCBM molecule is close enough to a MDMO-PPV polymer strand. As such, this mechanism may occur anywhere within the volume of the composite 44. The potential difference within the CBPD 40 will separate these charge carriers and support the selective transport of the carriers to the proper electrodes. The electrons 56 transfer to the negative electrode via the acceptor molecules PCBM 52.

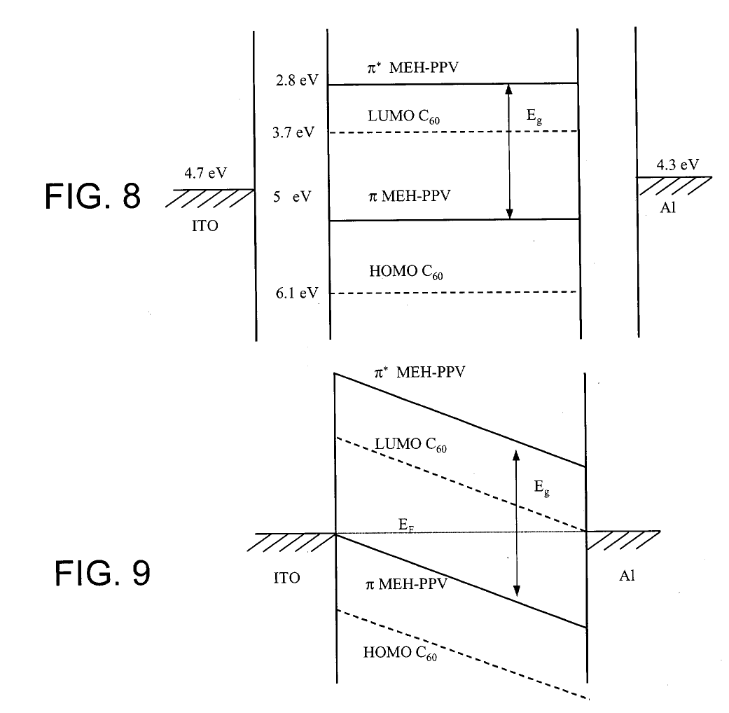

FIG. 8 shows the energy levels for composite 44 under flat band conditions. FIG. 9 shows the energy levels for composite 44 under short circuit conditions. Both clearly show the lack of spatial discontinuity in the energy of electron levels throughout composite 44.

MDMO-PPV 50 is one example of a conjugated polymer acting as a p-type semiconductor. Another type of conjugated polymer that may act as a p-type semiconductor is regioregular polythophenes such as poly(3-hexylthiophene) (P3HT). Regioregular polythophenes have a tendency to form 2-dimenisonal intrachain aggregates do to enhanced π stacking. In π stacking, π bond molecules in he chain interact. This yields a much higher carrier mobility.

The above embodiments of polymer/small molecule CBPDs all are p-n photodiodes. However, such CBPDs may take the form of any many types of photodiodes, such as PIN, drift, and avalanche photodiodes. Furthermore, similar to inorganic photodiodes, CBPDs may be operated in photovoltaic or photodetector modes (no bias or reverse bias, respectively).

Table 1 summarizes some of the major opto-electronic characteristics of an illustrative CBPD versus some inorganic photodiodes. Quantum efficiency is the ratio of the number of output quanta to the number of input quanta. Note that the dark current is due to thermal leakage. The data for the Carbon Based PIN Photodiode is subject to rapid change due to continued research in the field. The data for the Inorganic PIN Photodiode is taken from a Hamamatsu s-3204-05 Si PIN photodiode. The data for the Avalanche Photodiode is taken form a Hamamatsu S3884 Si APD. The data for the Silicon Drift Detector is taken from the article Proc. SPIE, vol. 4141:97-110, 2000.

TABLE 1

| | Carbon | | | Inorganic |
|---|---|---|---|---|
| | Based | Inorganic | Inorganic | (Silicon) |
| | PIN | PIN | Avalanche | Drift |
| | Photodiode | Photodiode | Photodiode | Detector |
| Quantum | >60 | 50 | 50 | ˜70 |
| Efficiency for | | | | |
| Nal(TI) | | | | |
| (λ = 420 nm) | | | | |
| Quantum | >80 | 70 | 70 | ˜80 |
| Efficiency for | | | | |
| Csl(TI) | | | | |
| (λ = 560 nm) | | | | |
| Dark Current | 2.5 | 4.6 | 15.3 | 1.0 |
| (nA/cm²) | | | | |
| Detector | 250 | 24.7 | 483 | 0.15 |
| Capacitance | | | | |
| (pF/cm²) | | | | |

A major factor in the effectiveness of a photodiode in the present application is the amount of electrical noise that the operating photodiode introduces into the detector system. Noise in photodiodes arises from two main sources. Series noise arises primarily from sources within the preamplifier input stage, and it relative importance increases with detector capacitance in a photodiode. Parallel noise is due largely to the leakage current caused by thermal fluctuations in the photodiode.

In photodiodes such as CBPDs, the capacitance is directly proportional to the electrode area. See Table 1. The thickness of the photodiode is inversely proportional to the capacitance of a CBPD. Therefore, reducing the electrode area and the increasing the thickness of a CBPD will lower the capacitance. However, increasing the thickness causes a decrease in the number of electrons that can escape the volume of the CBPD. More specifically, the lower electron mobility within CBPDs as compared to inorganic photodiodes, and the consequent smaller product of electron mobility and electron lifetime, results in an increased electron path due to increased thickness of the CBPD which will result in a smaller measurable current. To avoid this problem, the CBPD must be operated in photodetector mode. Hence, the application of a reverse bias is required to attain high efficiencies.

Thermal leakage, which also may be called dark current, is greatly reduced in CBPDs due to the larger band gap of CBPDs. See Table 1. Therefore, parallel noise may be much smaller in radiation detectors which use CBPDs rather than inorganic photodiodes. Thus both serial and parallel noise in a detector using CBPDs can be much lower than those using inorganic photodiodes if the structure of CBPD is optimized and a reverse bias is applied.

In addition to the high quantum efficiency, CBPDs have several advantages over inorganic photodiodes. They are inexpensive, and easy to manufacture. In particular, CBPDs which may be manufactured by a solution process may be mass produced quickly and easily using techniques well known in the plastics art. The mechanical structure of CBPD is thin and flexible. Together, these two properties lend themselves to the use of arrays of small, cheaply photodiodes. Further, CBPDs are more resistant to radiation damage. CBPDs have spectral response that covers most scintillators used in nuclear medicine, and are optimum for the common scintillators of NaI and CsI. Finally, the large band gap of CBPDs yield a low thermally generated dark current, which gives lower noise.

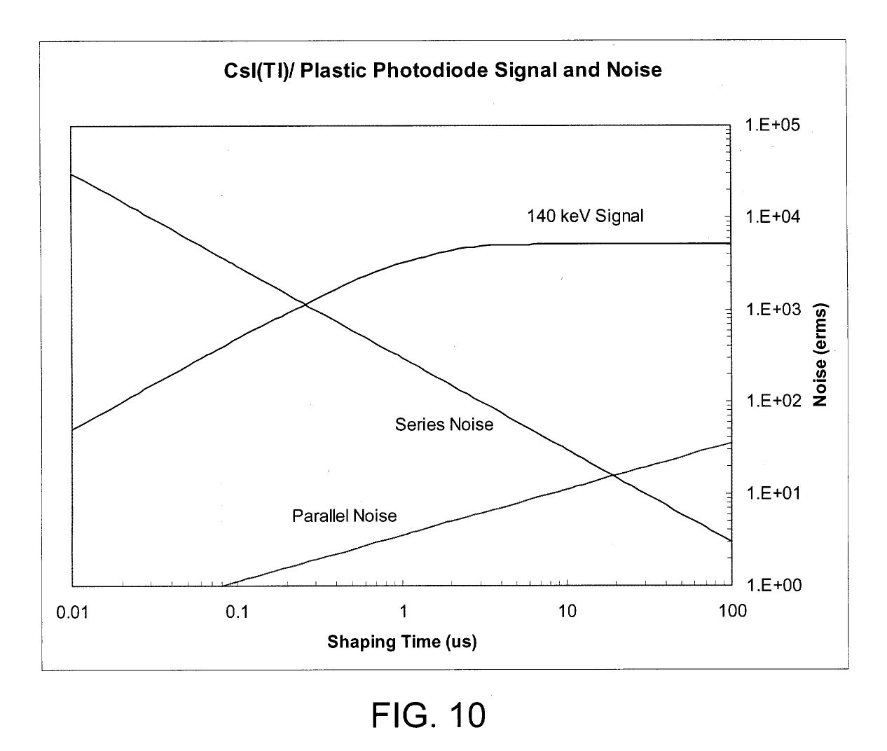

FIGS. 10-12 demonstrates the performance of a detector system which is an illustrative embodiment of the present invention. The detector system is similar to the system shown in FIG. 1, and includes a CsI(TI) scintillator and a CBPD. In determining the performance of the illustrative detector system, the CsI(Tl) is assumed to have a thickness of 1 cm, a mass of 4.51 g/cm³, to produce light of 0.052 photons/eV absorbed, to have a primary decay time of 1 μs, and to emit scintillation photons of an average wavelength of 565 nm and a photon energy of 2.2 eV. The CBPD is assumed to have an External Quantum Efficiency (EQE) of 0.8 at 565 nm, a sensitivity of 0.5 A/W, a light collection efficiency of 80%, a capacitance of 50 pF/pixel, and a leakage current of 1 pA/pixel. The system is assumed to have a series Equivalent Noise Charge (ENC) of 50+10 pF for 0.5 μs, a stray capacitance of 5 pF, and a pixel size of 2 mm×2 mm, wherein a pixel refers to is a single photodiode in an array of photodiodes that make up the carbon-based photodiode detector.

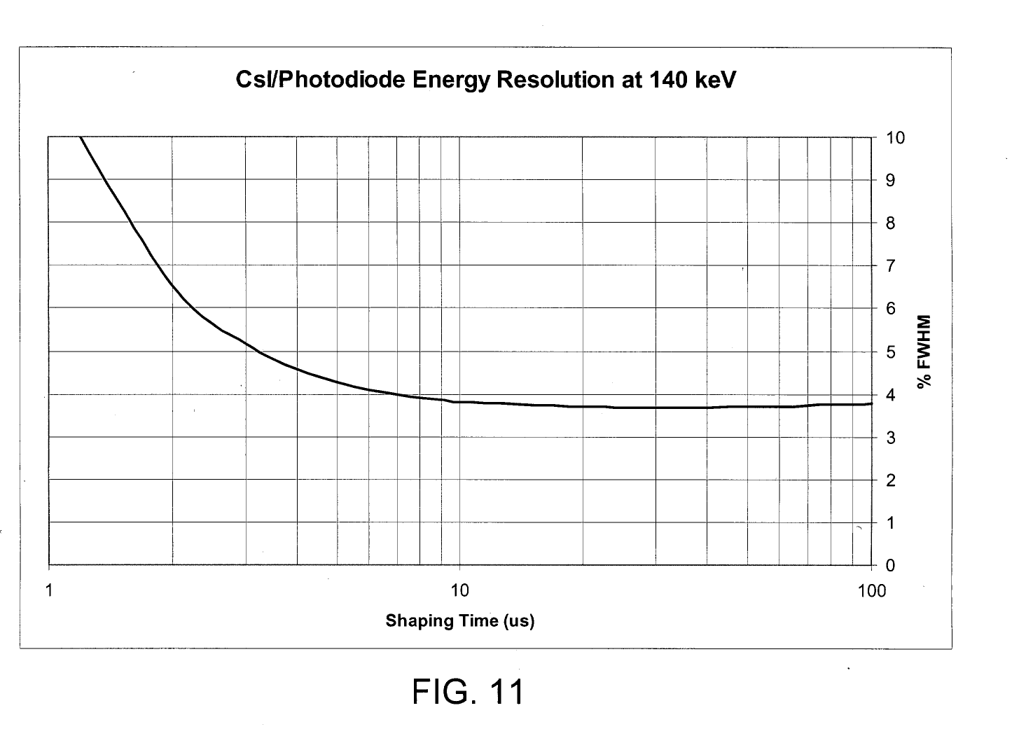

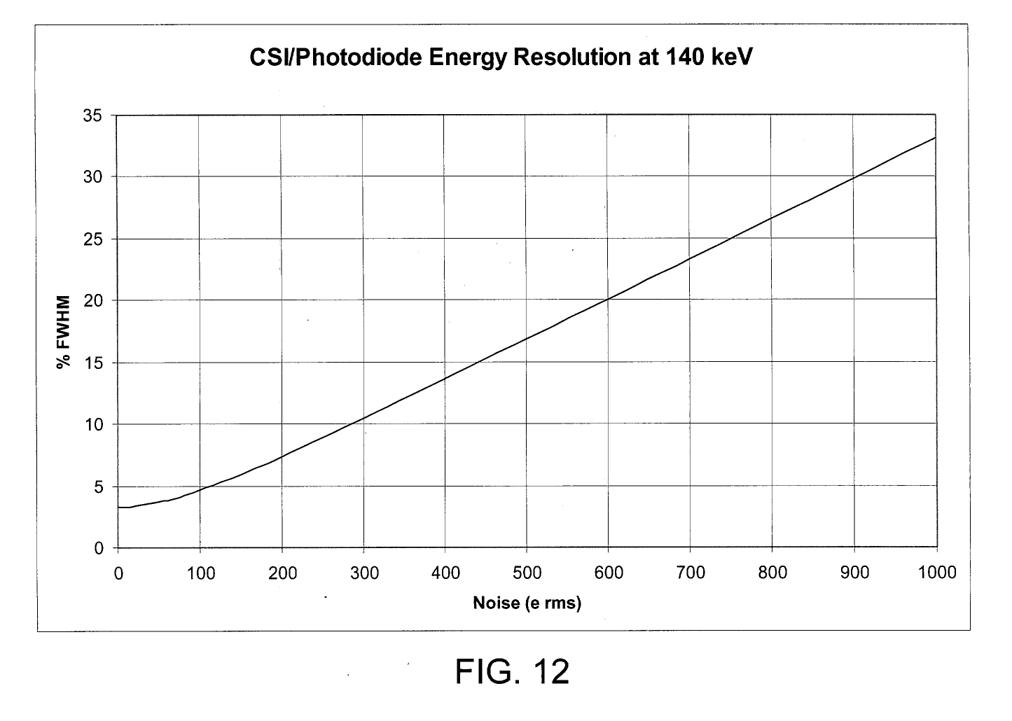

FIG. 10 shows the shaping time (in microseconds) versus noise (root mean square) in the illustrative system. The shaping circuit 16 acts as an integrator, such that the peak value of the shaped signal is proportional to the total collected signal. As FIG. 10 illustrates, if the shaping time is less than five times the decay time characteristic of the scintillator, a “ballistic deficit” occurs. Other scintillators have shorter decay times, allowing correspondingly shorter shaping times. The calculated system energy resolution as a function of shaping time for this idealized setup is shown in FIG. 11. This is based on the intrinsic energy resolution of the CsI(TI) crystal, which is statistical in nature, and the simple model of parallel and series electronic noise. FIG. 12 shows the energy resolution (% FWHM) vs. noise (electrons rms). Current NaI(TI)/PMT systems achieve a nominal 10% energy resolution at 140 keV. To match this performance, the CsI(TI)/CBPD system would require a shaping time above 1 [symbol] s and a total electronic noise less than 320 e rms. The potential for achieving energy resolutions superior to the traditional NaI/PMT system clearly can be seen.

Another advantage of CBPDs is the potential for tailoring of the material for a specific kind of scintillator. Furthermore, CBPDs may be used to detect x-rays, possibly yielding a dual use medical detector.

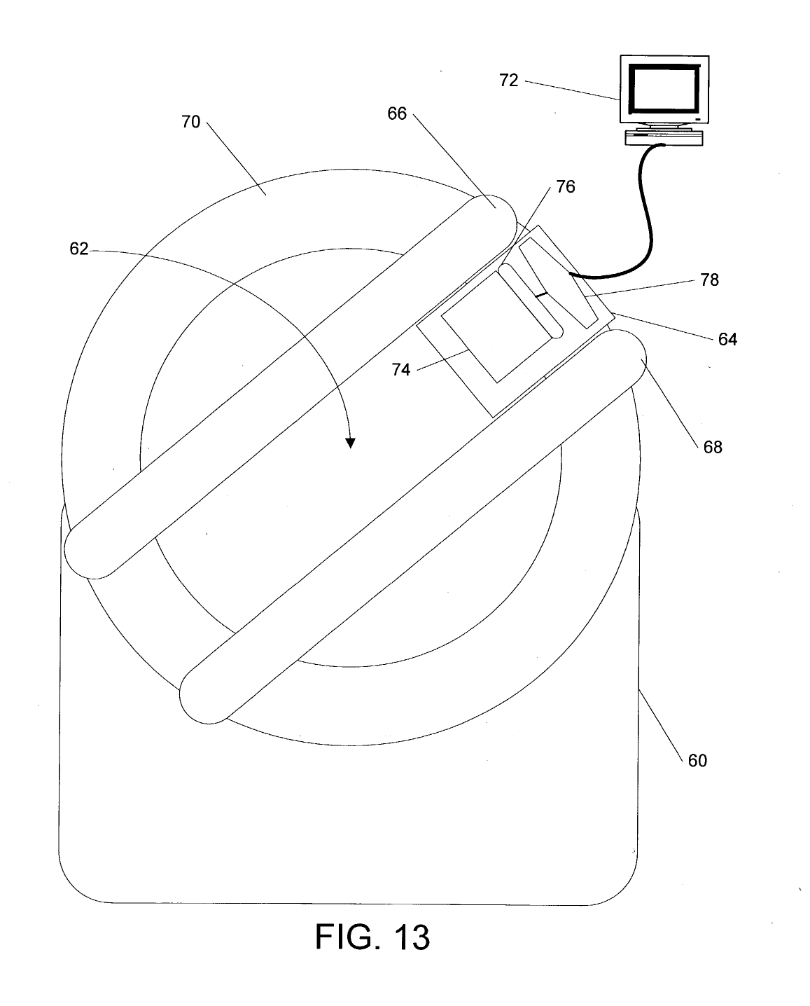

FIG. 13 is an example of an application of CBPDs to a radiation detection assembly as might be used for nuclear medicine imaging in a clinical setting. The gantry 60 has an aperture 62 through which a patient may fit. The radiation detector housing 64 is mounted between tracks 66 and 68. Tracks 66 and 68 are mounted onto rotating collar 70. The radiation detector housing 64 may thus be translated along the tracks and rotated around the axis through the aperture 62. A computer 72 is in communication with radiation detector housing 64. The computer 72 is shown detached from gantry 60, but it may be integral with the gantry 60, the camera housing 64, or distributed in any manner. The radiation detector housing 64 contains a scintillator 74, a CBPD 76, and acquisition electronics 78, as described hereinabove.

Some of the discussed embodiments of carbon-based photodiodes have used fullerenes of various forms to act as n-type semiconductors, in other charge acceptors. There are other materials which also significantly enhance the performance of conjugated polymers as photodiodes. Specifically, certain nanoparticles may act as very effective charge acceptors when used with conjugated polymers, yielding enhanced performance of carbon-based photodiodes. Specific examples of nanoparticles useful for such applications include nanoparticles of Cadmium Telluride (CdTe), Cadmium Selenide (CdSe), and Copper Indium Selenide (CuInSe). In this particular application, the size of the nanoparticles will range from 1 nm to 150 nm (the thickness of the polymer layer). In general, larger nanoparticles yield better performance as charge acceptors.

As these and other variations and combinations of the features discussed above can be utilized, the foregoing description of the preferred embodiments should be taken by way of illustration rather than by limitation of the invention set forth in the claims.

What is claimed is:

1. A radiation detector comprising a scintillator and a carbon-based photodiode array optically coupled to the scintillator.

2. The radiation detector of claim 1, wherein the carbon-based photodiode array includes at least one carbon-based photodiode.

3. The radiation detector of claim 2, wherein each carbon-based photodiode includes a p-type semiconductor and an n-type semiconductor.

4. The radiation detector of claim 3, wherein each carbon-based photodiode has a bulk heterojunction region.

5. The radiation detector of claim 4, wherein the bulk heterojunction region comprises nanoscopic p-n junctions formed from the blend of the p-type semiconductor and the n-type semiconductor.

6. The radiation detector of claim 5, wherein the p-type semiconductor comprises a conjugated polymer, and the n-type semiconductor comprises a fullerene.

7. The radiation detector of claim 6, wherein the fullerene includes PCBM.

8. The radiation detector of claim 6, wherein the polymer includes MDMO-PPV.

9. The radiation detector of claim 6, wherein the polymer includes P3HT.

10. The radiation detector of claim 3, wherein each carbon-based photodiode has a single planar heterojunction.

11. The radiation detector of claim 10, wherein the single planar heterojunction is formed from the p-type semiconductor and the n-type semiconductor.

12. The radiation detector of claim 11, wherein the p-type semiconductor comprises a conjugated polymer semiconductor, and the n-type semiconductor comprises a fullerene semiconductor.

13. The radiation detector of claim 12, wherein the polymer semiconductor comprises MDMO-PPV.

14. The radiation detector of claim 13, wherein the fullerene semiconductor comprises C60.

15. The radiation detector of claim 2, wherein the at least one carbon-based photodiode is a PIN photodiode.

16. The radiation detector of claim 2, wherein the at least one carbon-based photodiode is an avalanche photodiode.

17. The radiation detector of claim 2, wherein the at least one carbon-based photodiode is a drift photodiode.

18. The radiation detector of claim 2, wherein the at least one carbon-based photodiode is a Schottky photodiode.

19. A radiation detector system comprising a scintillator, a carbon-based photodiode array optically coupled to the scintillator, and electronic circuits electrically coupled to the carbon-based photodiode array.

20. The radiation detector system of claim 19, wherein the carbon-based photodiode array includes at least one carbon-based photodiode.

21. The radiation detector system of claim 20, wherein the at least one carbon-based photodiode includes a p-type semiconductor and an n-type semiconductor.

22. The radiation detector system of claim 21, wherein the at least one carbon-based photodiode has a bulk heterojunction region.

23. The radiation detector system of claim 22, wherein the bulk heterojunction region comprises nanoscopic p-n junctions formed from the blend of the p-type semiconductor and the n-type semiconductor.

24. A method of detecting gamma rays or x-rays, comprising receiving gamma ray photons in a scintillator, emitting lower wavelength photons in reaction to receiving the x-ray or gamma ray photon from the scintillator, receiving the lower wavelength photons in a carbon-based photodiode optically coupled to the scintillator, creating electron hole-pairs in reaction to receiving the lower wavelength photons, changing the electrical characteristic measured from the carbon-based photodiode in reaction to creating the electron hole-pairs.

25. A radiation detector assembly comprising a gantry, and a radiation detector system mounted on the gantry, and a computer in communication with the radiation detector system, wherein the radiation detector system includes a radiation detector and associated electronics, the radiation detector including a scintillator and a carbon-based photodiode array.

26. The radiation detector of claim 5, wherein the p-type semiconductor comprises a conjugated polymer, and the n-type semiconductor comprises a nanoparticle.
